(19) United States
(12) Patent Application Publication
(10) Pub. No.: US 2008/0153305 A1
(43) Pub. Date: Jun. 26, 2008

(54) PASSIVATING METAL ETCH STRUCTURES

(76) Inventor: Ted Liang, Sunnyvale, CA (US)

Correspondence Address: INTEL CORPORATION;c/o INTELLEVATE, LLC, P.O. BOX 52050, MINNEAPOLIS, MN, 55402, US

(21) Appl. No.: 11/940,154

(22) Filed: Nov. 14, 2007

Related U.S. Application Data
(62) Division of application No. 11/015,072, filed on Dec. 17, 2004, now abandoned.

(51) Int. Cl. H01L 21/302

(52) U.S. Cl. 438/712; 216/94; 257/E21.214

(57) ABSTRACT

A method to passivate a freshly etched metal structure comprises providing a metal surface on a substrate that has been etched by a first particle beam, exposing the metal surface to a passivation gas, and exposing the freshly etched metal structures to a second particle beam in the presence of the passivation gas. The second particle beam may comprise an ion beam or a laser beam. The passivation gas may comprise water vapor, oxygen gas, or hydrocarbon gas.

### CROSS-REFERENCE TO RELATED APPLICATIONS

This is a Divisional Application of U.S. patent application Ser. No. 11/015,072, filed on Dec. 17, 2004, which is presently pending.

### BACKGROUND

In modern integrated circuit transistors, such as complementary metal oxide silicon (CMOS) transistors, metal etching processes are becoming much more important. This is because metals are being used to a greater degree in forming small scale transistor components. For instance, metal is replacing polysilicon as the material of choice for gate electrodes. Such gate electrodes are made using a metal deposition process followed by a metal etching process to define the gate. Metal etching processes may also be used for mask repair and circuit editing where metal structures need to be modified locally by etching away materials.

Metals that are good candidates for scaled down transistor components and that are easily etched include tungsten (W), molybdenum (Mo), molybdenum-silicon (MoSi), tantalum (Ta), tantalum nitride (TaN), titanium (Ti), titanium nitride (TiN), TaSiₓN_{y}, alloys such as Ta, boron (B), and nitrogen (TaBN), or any combination of these metals or alloys. The etching process may use particle beam induced chemical etching technologies such as electron beam etching, ion beam etching, or laser etching. These particle beam etching processes are generally carried out in the presence of an etching gas such as xenon difluoride (XeF₂). Specifically, such processes may be used for local nanostructuring with focused beam.

One drawback to etching metals using particle beam etching processes is that once the etching process ceases, the freshly exposed surfaces of the metal remain in a highly reactive state. These highly reactive surfaces are susceptible to further etching of the metal structure simply by remaining in the presence of the etching gas, even though the particle beam is no longer being applied. The result of this further etching is degradation or destruction of the newly defined metal structures. FIG. 1 illustrates etched metal structures 100 that have been degraded due to further etching that occurred after the particle beam etching process was stopped. The regions of over-etching are shown as halos 102.

### BRIEF DESCRIPTION OF THE DRAWINGS

FIG. 1 illustrates metal structures that were over-etched using a conventional metal etching process.

FIG. 2 is a method for passivating metal structures in accordance with an implementation of the invention.

FIG. 3 illustrates the passivation of metal structures according to an implementation of the invention.

FIG. 4 illustrates metal structures that have been passivated in accordance with the invention.

### DETAILED DESCRIPTION

Described herein are systems and methods for stabilizing metal structures on a substrate, such as a semiconductor wafer or a photomask, that are etched by particle beams. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide a passivation process that may stabilize metal structures formed using particle beam etching processes, including but not limited to electron beam etching, ion beam etching, and laser beam etching. As described above, the freshly exposed surfaces of the metal tend to remain in a highly reactive state after the particle beam etching process. The passivation process of the invention may be used to treat these freshly exposed surfaces to reduce or eliminate their reactivity. By reducing the reactivity of the freshly exposed surfaces, the invention may stabilize the metal structures and substantially minimize or eliminate the post-etch degradation of the metal structures that often occurs.

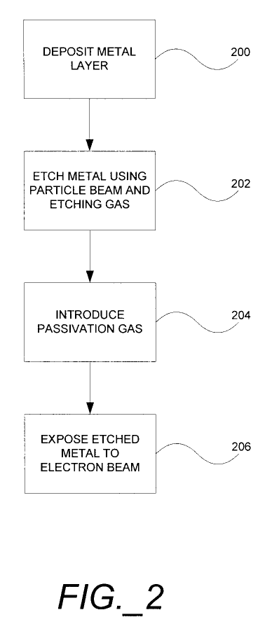

FIG. 2 is an in-situ passivation process for use on metal structures in accordance with an implementation of the invention. The metal structures may be formed using any metals that are typically used in semiconductor applications, including but not limited to tungsten (W), molybdenum (Mo), molybdenum-silicon (MoSi), tantalum (Ta), tantalum nitride (TaN), titanium (Ti), titanium nitride (TiN), TaSiₓN_{y}, alloys such as Ta, boron (B), and nitrogen (TaBN), and any combination of these metals or alloys.

The process begins with a layer of metal being deposited on a substrate, such as a semiconductor wafer (process 200). A particle beam etching process is then carried out on the metal layer in the presence of an etching gas to define one or more metal structures (202). The etching process is typically carried out within a chamber or other system appropriate for the type of particle beam used. For instance, electron beam etching is carried out in a system that includes an electron column and a vacuum chamber that houses a stage and a gas injection system. Different systems or chambers may be used for ion beam etching processes and laser beam etching processes. In implementations of the invention, the etching gas may include, but is not limited to, XeF₂.

After the metal structures are etched, a passivation gas is introduced into the chamber (204). In implementations of the invention, the passivation gas may include, but is not limited to, water vapor (H₂O) or oxygen gas (O₂). The pressure of the passivation gas near the surface of the metal structures may range from 50 to 1000 milliTorr (mTorr). In some implementations, the passivation gas may completely displace the etching gas in the chamber that was needed for the etching process. In other implementations, the passivation gas may be mixed with the etching gas. In some implementations of the invention, the etching gas may be evacuated from the chamber prior to introducing the passivation gas into the chamber.

In some implementations of the invention, the reactive surface of the metal structures may then be exposed to an a second particle beam in the presence of the passivation gas (206). The exposure may be performed by scanning an electron beam over the surface of the metal structures using either a raster scan or a serpentine scan. In some implementations, the area scanned by the electron beam may be greater than the surface area of the metal structure being passivated. In some implementations, the reactive surface of the metal structures may be exposed to an ion beam or a laser beam in the presence of the passivation gas instead of an electron beam.

In one implementation of the invention, the scanning parameters for the electron beam may include a voltage that ranges from 0.1 kilovolts (kV) to 5 kV, a dwell time that ranges from 0.1 microseconds (μs) to 5 μs, and a scan frame refresh time that ranges from 1 μs to 1 millisecond (ms). The scan frame refresh time will generally vary depending on the size of the area being passivated. In some implementations, the overall passivation time may range from 100 frames to 1000 frames. These process conditions are deemed optimized or sufficient for some implementations of the invention, however, process conditions different from those listed herein may be used to achieve certain results of varied performances in other implementations of the invention.

By exposing the reactive surface of the metal structures to the passivation gas, one or more layers of H₂O or O₂ are absorbed onto the reactive surface. The electron beam scanning over the surface causes the absorbed molecules to dissociate and form an oxide layer that may passivate the structure. In one implementation, the frame refresh time may be adjusted so that at least a monolayer of H₂O or O₂ is absorbed on the metal surface before the electron beam scans over the area again. When the surface of the metal structures absorbs one or more layers of H₂O or O₂, the reactivity of the surface is reduced or eliminated. This prevents further etching of the metal structures from occurring.

In some implementations, hydrocarbon gases may be used to passivate the metal surface structures. Electron beam induced deposition may cause the hydrocarbon gases to form a thin carbonaceous layer on a surface of a metal structure. Carbonaceous layers are generally inert to common etching gases such as XeF₂ and may therefore protect the freshly etched metal structures.

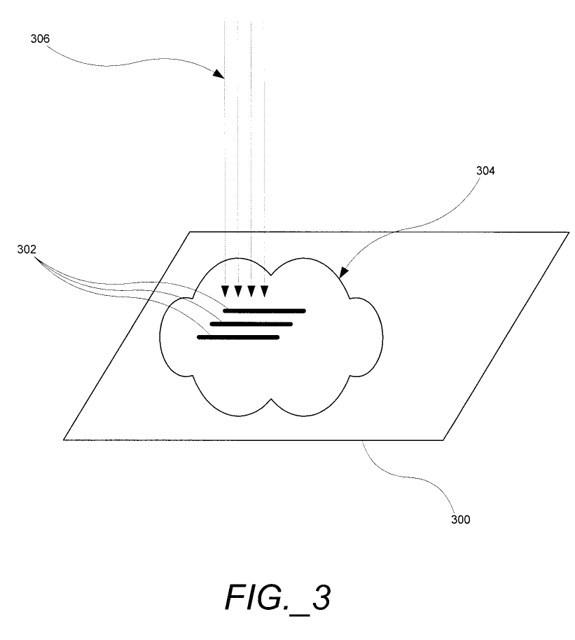

FIG. 3 illustrates the process described in FIG. 2. As shown, a substrate 300, such as a semiconductor wafer or a photomask, includes one or more freshly exposed metal structures 302. The metal structures 302 may include, but are not limited to, gate electrodes, interconnects, and structures on a photomask such as a TaN or TaBN absorber, and Mo—Si multilayer stacks. As described above, the metal structures 302 tend to have reactive surfaces after being etched by a particle beam process. A passivation gas 304, such as H₂O vapor or O₂ gas, is introduced in proximity to the metal structures 302 and tends to be absorbed by the reactive surfaces of the metal structures 302. An electron beam 306 is scanned across the metal structures 302 to cause the one or more layers of H₂O or O₂ to disassociate and form oxide layers on the metal structures 302 that reduce or eliminate their reactivity. This process therefore locally passivates the metal structures 302 and prevents further etching from occurring.

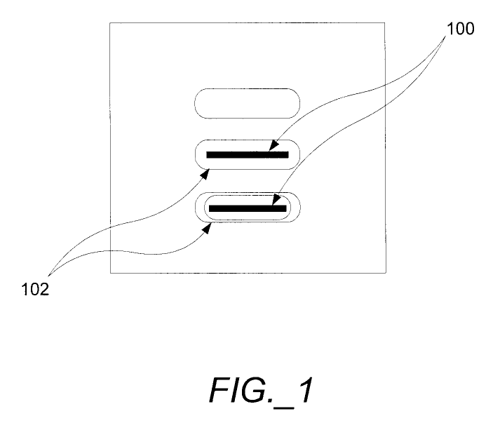

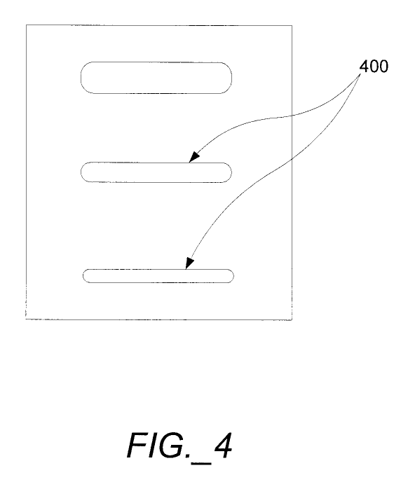

FIG. 4 is an illustration of passivated metal structures 400 formed in accordance with the methods of the invention. Unlike the metal structures 100 shown in FIG. 1, the passivated metal structures 400 of FIG. 4 do not suffer from over-etching and therefore do not contain the halos 102. Accordingly, the passivated metal structures 400 do not suffer from the degradation that occurs in conventional particle beam etching processes, which results in higher quality and more reliable metal structures.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a metal surface on a substrate that has been etched by a first particle beam;
exposing the metal surface to a passivation gas; and
exposing the metal surface to a second particle beam in the presence of the passivation gas, wherein the second particle beam comprises an ion beam or a laser beam.

2. The method of claim 1, wherein the first particle beam comprises an electron beam, an ion beam, or a laser beam.

3. The method of claim 1, wherein the metal surface comprises a surface formed from at least one of the following metals: tungsten, molybdenum, molybdenum-silicon, tantalum, tantalum nitride, titanium, titanium nitride, and TaSiₓN_{y}.

4. The method of claim 1, wherein the passivation gas comprises water vapor or oxygen gas.

5. The method of claim 1, wherein the substrate comprises a semiconductor wafer or a photomask.

6. A method comprising:
providing a metal surface on a substrate that has been etched by a first particle beam; and
forming an oxide layer on the metal surface by exposing the metal surface to a second particle beam in the presence of a passivation gas, wherein the second particle beam comprises an ion beam or a laser beam.

7. The method of claim 6, wherein the metal comprises one or more of tungsten, molybdenum, molybdenum-silicon, tantalum, tantalum nitride, titanium, titanium nitride, and TaSiₓN_{y}.

8. The method of claim 6, wherein the passivation gas comprises water vapor or oxygen gas.
